(19) United States
(12) Patent Application Publication
(10) Pub. No.: US 2008/0024167 A1
(43) Pub. Date: Jan. 31, 2008

(54) DESIGN STRUCTURE FOR IMPROVED DELAY VOLTAGE LEVEL SHIFTING FOR LARGE VOLTAGE DIFFERENTIALS

(75) Inventors: David J. Chen, Endwell, NY (US); Michael K. Kerr, Johnson City, NY (US); William F. Lawson, Vestal, NY (US)

Correspondence Address: CANTOR COLBURN LLP - IBM ROCHESTER DIVISION, 55 GRIFFIN ROAD SOUTH, BLOOMFIELD, CT, 06002, US

(73) Assignee: INTERNATIONAL BUSINESS MACHINES CORPORATION, Armonk, NY (US)

(21) Appl. No.: 11/869,071

(22) Filed: Oct. 9, 2007

Related U.S. Application Data
(63) Continuation-in-part of application No. 11/278,236, filed on Mar. 31, 2006, now Pat. No. 7,301,386.

(51) Int. Cl. H03K 19/0185

(52) U.S. Cl. 326/81; 326/80

(57) ABSTRACT

A design structure embodied in a machine readable medium used in a design process includes a voltage level shifting device for translating a lower operating voltage to a higher operating voltage, the voltage level shifting device including a first input node coupled to a first pull down device and a second input node coupled to a second pull down device, wherein the second node receives a complementary logic signal with respect to the first input node, the first and second input nodes associated with the lower operating voltage; a first pull up device in series with the first pull down device and a second pull up device in series with the second pull down device, the first and second pull up devices coupled to a power supply at the higher operating voltage; and an output node between the second pull down device and the second pull up device.

### CROSS-REFERENCE TO RELATED APPLICATIONS

This non-provisional U.S. patent application is a continuation in part of pending U.S. patent application Ser. No. 11/278,236, which was filed Mar. 31, 2006, and is assigned to the present assignee.

### BACKGROUND

The present invention relates generally to digital integrated circuits and, more particularly, to a design structure for improved delay voltage level shifting for large voltage differentials.

Over the last several years, CMOS-based (complementary metal-oxide semiconductor) integrated circuit (IC) technologies have been designed to operate with progressively lower power supply voltages with each passing generation. Lower supply voltages dictate lower voltage swings for the associated digital signals, which typically switch between ground and the power supply voltage. The benefits of using lower supply voltages include lower power consumption and faster signal switching times. On the other hand, lower supply voltages also result in lower noise margins. CMOS logic IC power supply voltages currently available include, for example, 3.3 V, 2.5 V, 1.8 V, 1.5 V and 1.0 V. Depending on the application, a mix of the various CMOS technologies may be used in any particular electronic product, thus necessitating the use of digital voltage level shifters to translate CMOS signals generated using one power supply voltage to signals based on a different voltage level.

FIG. 1 is a schematic diagram of an existing CMOS voltage level shifter 100 used to translate lower voltage signals (e.g., 1.0 V) to higher voltage signals (e.g., 3.3 V). As is shown, the level shifter includes four FETs, NFETs T1 and T2, as well as PFETs T3 and T4. The FETs of level shifter 100 are typically thick oxide devices, as the thin oxide devices used for 1.0 V signals cannot operate at the higher 3.3 V operating voltage. The input signals A and ABAR represent lower voltage signals and drive the gates of NFETs T1 and T2, respectively. Signal ABAR is the logical complement (NOT) of signal A. As also illustrated, the source terminals of NFET T1 and NFET T2 are connected to ground, while the source terminals of PFET T3 and PFET T4 are connected to the higher voltage supply (e.g., 3.3 V). The gate terminals of T3 and T4 are cross-coupled to the respective drain terminals thereof. The drain terminal of T3 is further connected to the drain terminal of T1, while the drain terminal of T4 is connected to the drain terminal of T2. The output signal Z represents the voltage level shifted value of input signal A.

For example, if A is logical 1 at the lower operating voltage (e.g., 1.0 V) and ABAR is logical 0 (ground), then Z is logical 1 at the shifted, higher operating voltage (e.g., 3.3 V). In this case, the 1.0 V input at A renders NFET T1 conductive, while the 0 V input at ABAR leaves NFET T2 off. As a result, the gate voltage of PFET T4 is pulled to ground, rendering it conductive. Accordingly the gate of T3 (and therefore output Z) is pulled up to the higher operating voltage, which also leaves PFET T3 non-conducting. Conversely, if A is at 0 V and ABAR is at 1.0 V, then NFET T1 is switched off while NFET T2 is switched on. The gate of PFET T3 is pulled toward ground, thereby switching it on, which in turn causes the gate voltage of PFET T4 to rise and thus switch it off. Conductive NFET N2 can then pull the output voltage at Z all the way to ground, unopposed by T4. When operating properly, CMOS level shifter 100 does not draw DC current.

However, the conventional level shifter 100 of FIG. 1 typically requires large NFET to PFET ratios for proper operation, which is unlike most CMOS circuits that usually require the PFET device to be larger than the NFETs to achieve a balanced output rise and fall delay. When translating low voltage CMOS signals typical in CMOS technologies of gate lengths below 0.18 μm to higher voltage signals, the NFET to PFET size ratio required by the circuit in FIG. 1 can be as large as 60:1 or sometimes as large 100:1. Such ratios are required in order to achieve proper operation over process variations, voltage variations, and temperature variations (PVT). More specifically, the large NFET versus PFET ratio is required because the low voltage signals driving the gates of NFETs T1 and T2 are very close to the Vt (threshold voltage) of these devices and therefore are not able to turn T1 and T2 on strongly. The gates of PFETs T3 and T4, on the other hand, are driven by the higher voltage signal (e.g., 3.3 V). Thus, when these devices are turned on, they are strongly turned on. As a result, PFETs T3 and T4 must be very small relative to NFETs T1 and T2 so as to balance the current drive capability of the PFETs versus the NFETs.

The requirement for this level shifting circuit to operate over large process, voltage, and temperature ranges further pushes the NFET to PFET ratio even larger for conditions where the low voltage is at its lower tolerance value, the high voltage is at its higher tolerance value, and where the chip manufacturing process has resulted in strong PFETs and weak NFETs. Because NFETs T1 and T2 are so large, the A and ABAR inputs must drive a large gate capacitance. These high ratios can also make PFET T4 very weak relative with respect to NFET T2 for many PVT conditions, such as when the manufacturing process has created weak PFETs and strong NFETs and when the lower voltage supply is at its higher tolerance value. Under these conditions, the circuit of FIG. 1 has both a large output rise delay and a large output rise delay to output fall delay mismatch. Even under nominal PVT conditions, the large gate input capacitance and weak PFET create a slow circuit and large rise/fall delay mismatches, both of which are undesirable.

Accordingly, there is a need for an improved CMOS level shifting device which overcomes the above described disadvantages and allows for smaller NFET devices, improved rise/fall delays and improved rise/fall delay mismatch characteristics, and which operates correctly over extreme PVT variations.

### SUMMARY

The foregoing discussed drawbacks and deficiencies of the prior art are overcome or alleviated by a design structure embodied in a machine readable medium used in a design process, the design structure including a voltage level shifting device for translating a lower operating voltage to a higher operating voltage, the voltage level shifting device including a first input node coupled to a first pull down device and a second input node coupled to a second pull down device, wherein the second node receives a complementary logic signal with respect to the first input node, the first and second input nodes associated with the lower operating voltage; a first pull up device in series with the first pull down device and a second pull up device in series with the second pull down device, the first and second pull up devices coupled to a power supply at the higher operating voltage; an output node between the second pull down device and the second pull up device, the output node controlling the conductivity of the first pull up device; a first inverter having an input connected to the output node; a second inverter having an input connected to an output of the first inverter, and an output of the second inverter connected to the output node; a switching device between the first pull up device and the first pull down device, the switching device controlled by the output of the first inverter; and a clamping device in parallel with the first pull up device, the clamping device configured to prevent the second pull up device from becoming fully saturated.

In another embodiment, a design structure embodied in a machine readable medium used in a design process includes a CMOS level shifter for including a first input node coupled to a first pull down NFET and a second input node coupled to a second pull down NFET, wherein the second node receives a complementary logic signal with respect to the first input node, the first and second input nodes associated with the lower operating voltage; a first pull up PFET in series with the first pull down NFET and a second pull up PFET in series with the second pull down NFET, the first and second pull up PFETs coupled to a power supply at the higher operating voltage; an output node between the second pull down NFET and the second pull up PFET, the output node controlling the conductivity of the first pull up PFET; a first inverter having an input connected to the output node; a second inverter having an input connected to an output of the first inverter, and an output of the second inverter connected to the output node; an NFET between the first pull up device and the first pull down device, a gate terminal of the NFET connected to the output of the first inverter; and a clamping device in parallel with the first pull up PFET, the clamping device configured to prevent the second pull up PFET from becoming fully saturated.

### BRIEF DESCRIPTION OF THE DRAWINGS

Referring to the exemplary drawings wherein like elements are numbered alike in the several Figures:

FIG. 1 is a schematic diagram of a conventional CMOS level shifter used to translate lower voltage signals to higher voltage signals;

FIG. 2 is a schematic diagram of a CMOS level shifter, in accordance with an embodiment of the invention;

FIG. 3 is a schematic diagram of a CMOS level shifter, in accordance with another embodiment of the invention; and

FIG. 4 is a flow diagram of an exemplary design process used in semiconductor design, manufacturing, and/or test.

### DETAILED DESCRIPTION

In the following description, exemplary values of 1.0 V and 3.3 V are used in conjunction with the terms “lower voltage” and “higher voltage”, respectively. However, it should be understood that the embodiments described herein are not limited to these specific voltages; one skilled in the art of circuit design will recognize that different values of voltages can be substituted for 1.0 V and 3.3 V, wherein the lower voltage is lower than or equal to the higher voltage. In other words, the present disclosure is applicable for shifting between any two desired operating voltage levels.

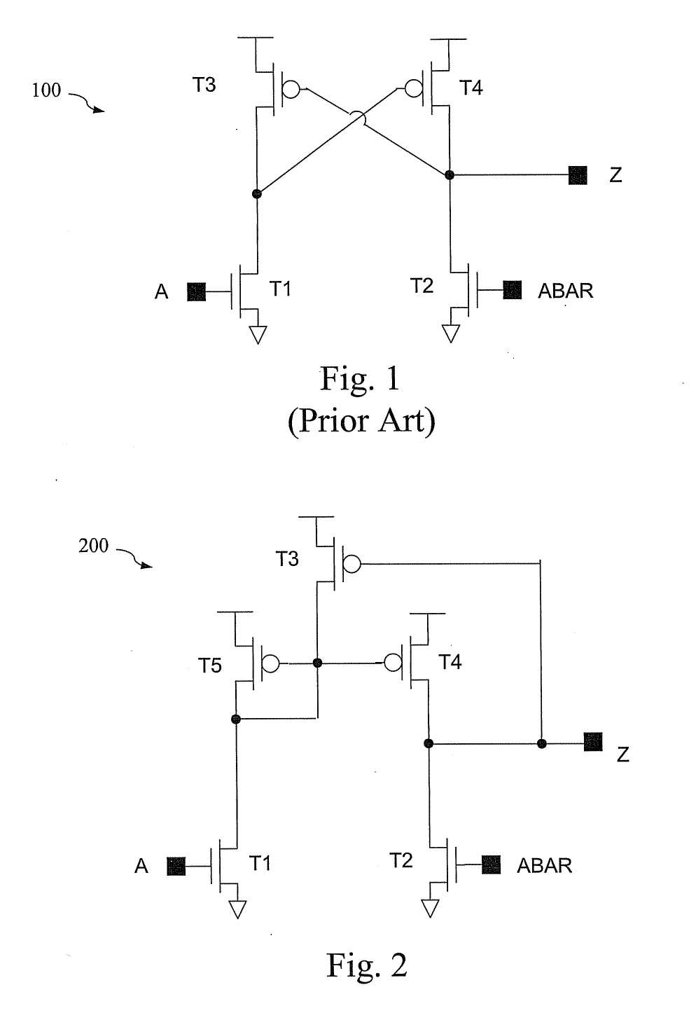

Referring now to FIG. 2, there is shown a schematic diagram of a CMOS level shifter 200, in accordance with an embodiment of the invention. As compared to the conventional device 100 of FIG. 1, level shifter 200 introduces a diode-configured PFET T5 (which acts as a clamping device) to the design of FIG. 1. The gate terminal of T3 remains connected to the drain terminal of T4 as before. However, the gate of T4 is now coupled to the shorted gate/drain terminals of T5, as well as to both the drain of NFET T1 and the drain of PFET T3. The combination of PFET T5 and NFET T1 create a common source amplifier that amplifies the signal driving the gate of T4. The ratio of T1 to (T5+T3) needed to drive the gate of T4 is now smaller than that ratio of T1 to T3 in FIG. 1, thereby resulting in a reduced falling delay. When input A transitions from 1.0 V to 0 V, the gate of T4 rises to the higher transition voltage (e.g., 3.3 V) faster that with respect to the shifter 100 of FIG. 1, thus more quickly switching T4 off and allowing NFET T2 to pull the output to 0 V more quickly. This circuit is also not as dependent on the feedback connection from the Z output to the gate of T3 to turn off T4, which also helps improve the falling delay.

On the other hand, because of the diode-configured PFET T5, there is a small amount of DC current that flows through T5 and T1 when input A is at 1.0 V. In addition, the embodiment of FIG. 2 (while providing an improvement in falling delay) does not provide a similar rising delay improvement; i.e., when the value of A rises from 0 V to 1.0 V. This is because T3 is still fully on when the output node Z is initially at 0 V, thus T1 does not receive any extra assistance in pulling down the gate voltage of T4 to raise the output node Z.

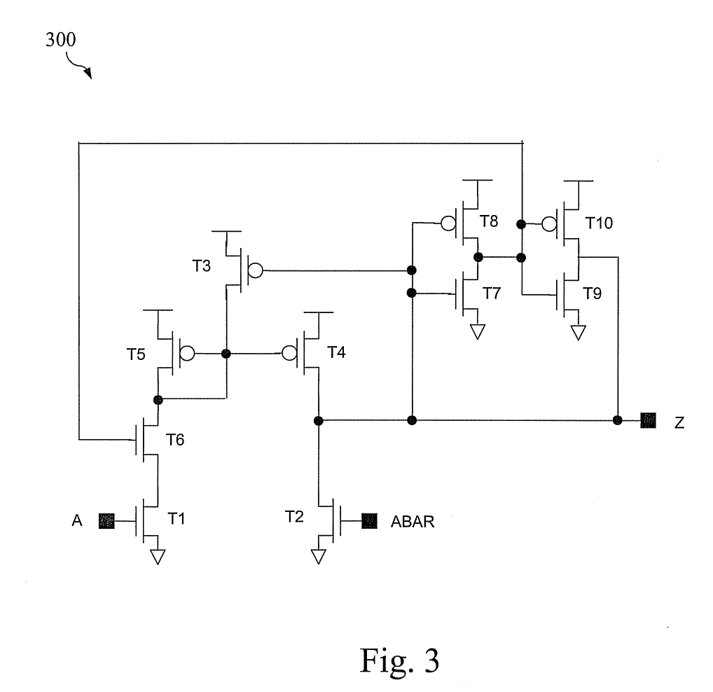

Accordingly, FIG. 3 is a schematic diagram of a CMOS level shifter 300, in accordance with an embodiment of the invention. As compared to the embodiment of FIG. 2, FIG. 3 further introduces NFETs T6, T7, T9 and PFETs T8, T10. More specifically, the source terminal of NFET T6 is connected to the drain of NFET T1 while the drain of T6 is connected to the drains of T3 and T5, as well as the gate of T4. The source terminals of PFETs T8 and T10 are connected to the higher voltage supply, while the source terminals of NFETs T7 and T9 are connected to ground. Furthermore, the gates of T8 and T7 are driven by the output Z. The drain terminals of T8 and T7 are connected to one another and drive the gates of T10 and T9. The drain terminals of T10 and T9 are connected together and drive the output Z.

Thus configured, devices T7, T8, T9, and T10 form a latch on the output Z and are all selected to be very small with respect to the other FET devices in the level shifter. A first inverter, defined by T7 and T8, drives the gate of NFET T6 and the input of a second inverter defined by T9 and T10. When the input A is initially at 0 V, the output node Z is at 0 V (as maintained by NFETs T2 and T9) and the gate of T6 is charged to 3.3 V (through conductive T8). Also, PFET T4 is off since the gate thereof is held at 3.3 V through conductive T3. Upon a rising transition, the series combination of T1 and T6 pulls the gate voltage of T4 down, thereby raising the output voltage on node Z toward 3.3 V. This in turn causes the output of the first inverter defined by T7 and T8 to transition from 3.3 V to 0 V, thereby causing the output of the second inverter defined by T9 and T10 to reinforce and latch the value of output node Z to 3.3 V. Because the output of T7 and T8 controls the gate of T6, T6 will be switched off, which then allows T5 to once again raise the voltage of the gate of T4 higher and making it weakly conductive or even turning it off altogether.

As T4 is not constantly maintained in a conductive state during a rising transition, the latch defined by T7, T8, T9 and T10 are therefore used to maintain the Z output at a high voltage level. Also, because T6 is off, there is no DC current path from PFET T5 to NFET T1 as in the case of the embodiment of FIG. 2. Conversely, during a falling transition, NFET T2 turns on to pull the output Z low. PFET T4 is switched off and thus NFET T2 need only overcome weak PFET T10. Once the voltage at node Z drops low enough, the gate of T6 is driven high by T8. This will allow T1 to operate correctly (i.e., activate T4) upon the next rising transition of A.

As indicated above, the latch devices T7, T8, T9 and T10 are kept to relatively minimum sizes. When the A input falls from logic 1 to logic 0, diode-configured T5 will have pulled the gate of T4 above its Vₜ and turned T4 off. Thus, T2 need only overcome the relatively small sized PFET T10 in order to pull output node Z down to 0v. As T10 is smaller than T4 in FIGS. 1 and 2, T2 of FIG. 1 may also be reduced in size, and the level shifter 300 will still operate correctly over all foreseeable PVT conditions. T2 is further aided by NFET T9 once the output voltage on node Z drops below the threshold of the latch and inverts its state.

Still another advantage of the embodiment of FIG. 3 is realized upon consideration of the fact that in the conventional device of FIG. 1 and the embodiment of FIG. 2, PFET T4 is turned on when A is logic 1. PFET T4 must be kept small enough for NFET T2 to overcome when A falls to 0 V. However, the circuit of FIG. 3 turns PFET T4 off when A is logic 1 so that the size of T4 does not effect the operation of NFET T2. This allows T4 to be increased greatly in size and thus greatly reduce the rising delay of the circuit.

Furthermore, the features of the circuit in FIG. 3 allow the input NFETs T1 and T2 to be reduced in size relative to the circuit of FIG. 2, while the size of T4 in FIG. 3 can be increased in size relative to the circuit of FIG. 2. The NFET to PFET ratio of T2 to T4 may be reduced to a more reasonable value of 4 to 1 or lower. All of these changes lead to a smaller circuit with improved rising and falling delays, as well as improved rise to fall delay mismatch characteristics, and a circuit that operates correctly over the extreme PVT variations required for a high yielding product.

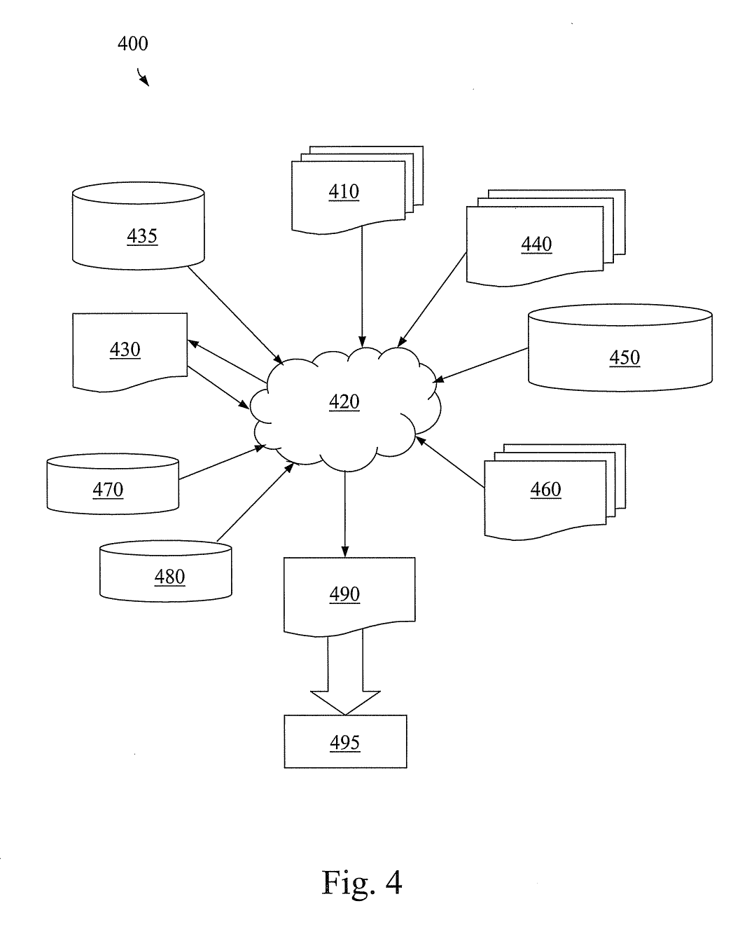

FIG. 4 is a block diagram illustrating an example of a design flow 400. Design flow 400 may vary depending on the type of IC being designed. For example, a design flow 400 for building an application specific IC (ASIC) will differ from a design flow 400 for designing a standard component. Design structure 410 is preferably an input to a design process 420 and may come from an IP provider, a core developer, or other design company or may be generated by the operator of the design flow, or from other sources. Design structure 410 comprises circuit embodiments 200, 300 in the form of schematics or HDL, a hardware-description language, (e.g., Verilog, VHDL, C, etc.). Design structure 410 may be contained on one or more machine readable medium(s). For example, design structure 410 may be a text file or a graphical representation of circuit embodiments 200, 300. Design process 420 synthesizes (or translates) circuit embodiments 200, 300 into a netlist 430, where netlist 430 is, for example, a list of wires, transistors, logic gates, control circuits, I/O, models, etc., and describes the connections to other elements and circuits in an integrated circuit design and recorded on at least one of machine readable medium 415. This may be an iterative process in which netlist 430 is resynthesized one or more times depending on design specifications and parameters for the circuit.

Design process 420 includes using a variety of inputs; for example, inputs from library elements 435 which may house a set of commonly used elements, circuits, and devices, including models, layouts, and symbolic representations, for a given manufacturing technology (e.g., different technology nodes, 32 nm, 45 nm, 90 nm, etc.), design specifications 440, characterization data 450, verification data 460, design rules 470, and test data files 480, which may include test patterns and other testing information. Design process 420 further includes, for example, standard circuit design processes such as timing analysis, verification tools, design rule checkers, place and route tools, etc. One of ordinary skill in the art of integrated circuit design can appreciate the extent of possible electronic design automation tools and applications used in design process 420 without deviating from the scope and spirit of the invention. The design structure of the invention embodiments is not limited to any specific design flow.

Design process 410 preferably translates an embodiment of the invention as shown in FIGS. 2 and 3, along with any additional integrated circuit design or data (if applicable), into a second design structure 490. Second design structure 490 resides on a storage medium in a data format used for the exchange of layout data of integrated circuits (e.g. information stored in a GDSII (GDS2), GL1, OASIS, or any other suitable format for storing such design structures). Second design structure 490 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 2 and 3. Second design structure 490 may then proceed to a stage 495 where, for example, second design structure 490: proceeds to tape-out, is released to manufacturing, is released to a mask house, is sent to another design house, is sent back to the customer, etc.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A design structure embodied in a machine readable medium used in a design process, the design structure comprising:
a voltage level shifting device for translating a lower operating voltage to a higher operating voltage, the voltage level shifting device including a first input node coupled to a first pull down device and a second input node coupled to a second pull down device, wherein the second node receives a complementary logic signal with respect to the first input node, the first and second input nodes associated with the lower operating voltage;
a first pull up device in series with the first pull down device and a second pull up device in series with the second pull down device, the first and second pull up devices coupled to a power supply at the higher operating voltage;
an output node between the second pull down device and the second pull up device, the output node controlling the conductivity of the first pull up device;
a first inverter having an input connected to the output node;
a second inverter having an input connected to an output of the first inverter, and an output of the second inverter connected to the output node;
a switching device between the first pull up device and the first pull down device, the switching device controlled by the output of the first inverter; and
a clamping device in parallel with the first pull up device, the clamping device configured to prevent the second pull up device from becoming fully saturated.

2. The design structure of claim 1, wherein transistors of the first and second inverters are of weaker strength with respect to the pull up and pull down devices.

3. The design structure of claim 1, wherein a size ratio of the second pull down device to the second pull up device is about 4:1 or less.

4. The design structure of claim 1, wherein the clamping device comprises a diode configured transistor.

5. The design structure of claim 1, wherein the design structure comprises a netlist describing the voltage level shifting device.

6. The design structure of claim 1, wherein the design structure resides on storage medium as a data format used for the exchange of layout data of integrated circuits.

7. The design structure of claim 1, wherein the design structure includes at least one of test data files, characterization data, verification data, programming data, or design specifications.

8. A design structure embodied in a machine readable medium used in a design process, the design structure comprising:
a CMOS level shifter for translating a lower operating voltage to a higher operating voltage, the CMOS level shifter comprising a first input node coupled to a first pull down NFET and a second input node coupled to a second pull down NFET, wherein the second node receives a complementary logic signal with respect to the first input node, the first and second input nodes associated with the lower operating voltage;
a first pull up PFET in series with the first pull down NFET and a second pull up PFET in series with the second pull down NFET, the first and second pull up PFETs coupled to a power supply at the higher operating voltage;
an output node between the second pull down NFET and the second pull up PFET, the output node controlling the conductivity of the first pull up PFET;
a first inverter having an input connected to the output node;
a second inverter having an input connected to an output of the first inverter, and an output of the second inverter connected to the output node;
an NFET between the first pull up device and the first pull down device, a gate terminal of the NFET connected to the output of the first inverter; and
a clamping device in parallel with the first pull up PFET, the clamping device configured to prevent the second pull up PFET from becoming fully saturated.

9. The design structure of claim 8, wherein transistors of the first and second inverters are of weaker strength with respect to the PFET and NFET devices.

10. The design structure of claim 9, wherein a size ratio of the NFET to the PFET is about 4:1 or less.

11. The design structure of claim 9, wherein the clamping device comprises a diode configured PFET.

12. The design structure of claim 8, wherein the design structure comprises a netlist describing the CMOS level shifter.

13. The design structure of claim 8, wherein the design structure resides on storage medium as a data format used for the exchange of layout data of integrated circuits.

14. The design structure of claim 8, wherein the design structure includes at least one of test data files, characterization data, verification data, programming data, or design specifications.
